(19) United States
(12) Patent Application Publication
(10) Pub. No.: US 2004/0124538 A1
(43) Pub. Date: Jul. 1, 2004

(54) Multi-layer integrated semiconductor structure

(76) Inventors: Rafael Reif, Newton, MA (US); Shamik Das, Watertown, MA (US); Andy Fan, Cambridge, MA (US)

Correspondence Address: DALY, CROWLEY & MOFFORD, LLP, SUITE 101, 275 TURNPIKE STREET, CANTON, MA, 02021-2310, US

(21) Appl. No.: 10/655,854

(22) Filed: Sep. 5, 2003

Related U.S. Application Data
(60) Provisional application No. 60/437,549, filed on Dec. 31, 2002.

(51) Int. Cl. H01L 23/48; H01L 29/40

(52) U.S. Cl. 257/774; 257/686; 257/692; 257/784

(57) ABSTRACT

A multi-layer integrated semiconductor structure including a first device layer having a first plurality of semiconductor elements. A first insulating layer is disposed over the first device layer and includes at least a first via-hole. A first conductive plug is disposed in the first via-hole. An interface portion is disposed over at least the first conductive plug. The multi-layer integrated semiconductor structure further includes a second device layer. The second device layer includes a second plurality of semiconductor elements disposed on a top surface of a substrate, which includes a second via-hole. A second conductive plug is disposed in the second via-hole. The second device layer is aligned and coupled to the first device layer via the interface portion so that the interface portion provides a communication relationship between the first device layer and the second device layer.

### CROSS REFERENCE TO RELATED APPLICATION

This application claims the benefit of U.S. Provisional Application No. 60,437,549, filed on Dec. 31, 2002, entitled, A Multi-Layer Integrated Semiconductor Structure, which is hereby incorporated by reference in its entirety.

### FIELD OF THE INVENTION

The present invention relates generally to a multi-layer integrated semiconductor structure and, more specifically, to a multi-layer integrated semiconductor structure that includes one or more conductor filled via-holes adapted to electrically couple active devices and/or conductive members of one device layer with active devices and/or conductive members of another device layer.

### BACKGROUND

A semiconductor device such as an integrated circuit generally has electronic circuit elements, such as transistors, diodes, resistors, capacitors and inductors, which are fabricated integrally on a single body of semiconductor material. The various circuit elements can be connected using connectors, conductive interconnects or conductor filled vias, to form a complete circuit that may contain millions of individual circuit elements. Typically, conductive interconnects form lateral connections (e.g., between electronic circuit elements on an integrated circuit) while conductor filled vias form vertical connections (e.g., between electronic circuit elements and lateral interconnects or between two or more lateral interconnects located on different layers of the integrated circuit). Thus, connections on the same layer of an integrated circuit are sometimes referred to as “horizontal connections” while connections between different layers of the same integrated circuit are referred to as “vertical connections.”

To provide a vertical connection using a conductor filled via (or more simply a via) it is first necessary to form a “via-hole.” Conventionally, a dielectric layer (e.g., silicon oxide) is deposited over the devices, and via-holes are patterned and formed through the dielectric layer to the devices below. As is well known in the art, photolithography “patterning” is typically accomplished by depositing a photoresist layer over the dielectric layer, selectively exposing the photoresist to light through a patterned reticle having via-hole patterns, developing the photoresist to form a resist via mask, and etching the exposed dielectric layer to form via-holes (e.g., extending from an exposed surface of the dielectric layer to a layer below the dielectric layer, such as the device layer).

Once the via-holes are formed, a conductive material (e.g., tungsten) is used to fill the via-holes to provide a conductive path or plug between a conducting surface in the layer below the dielectric layer (e.g., the device layer), and a lateral interconnect located above the dielectric layer. In the case where the via-holes are filled with tungsten, the conductive path is sometimes referred to as a tungsten plug. Once the conductive via-holes are formed, a metallization layer is often disposed over the dielectric layer. The metallization layer is then patterned using conventional photolithography techniques to provide a first layer of conductive interconnects or lines. This process may then be repeated if additional layers of conductive lines are desired.

One problem, however, is that conventional techniques for interconnecting increasingly greater numbers of circuit elements located on an integrated circuit using the lateral and vertical connections, as described above, requires a relatively large amount of area on the integrated circuit. This problem is exacerbated since advances in semiconductor materials and processing techniques have resulted in a trend to reduce the overall device size in an integrated circuit, while increasing the number of devices and circuit elements located on an integrated circuit.

To further increase the number of circuit elements per unit surface area in an integrated circuit and also to increase performance of integrated circuits, there has also been a trend to “stack” one semiconductor device layer over another semiconductor device layer. In such a stacked arrangement, it is relatively difficult to connect circuit elements in the first semiconductor device layer to circuit elements in the second semiconductor device layer.

It would, therefore, be desirable to provide a structure and technique for providing a multi-layer semiconductor structure having a coupling structure which provides inter- and intra-layer coupling between various circuit elements and interconnects located on various levels of a multi-layer semiconductor structure while occupying a relatively small amount of space.

### SUMMARY OF THE INVENTION

A multi-layer integrated semiconductor structure is set forth in accordance with principles of the present invention. The multi-layer integrated semiconductor structure includes a first device layer including a first plurality of semiconductor elements. At least a first insulating layer is disposed over the first device layer and includes at least a first via-hole. A first conductive plug is disposed in the first via-hole and an interface portion is disposed over at least the first conductive plug.

The multi-layer integrated semiconductor structure further includes a second device layer including a second plurality of semiconductor elements, which includes a second via-hole. A second conductive plug is disposed in the second via-hole. The second device layer is coupled to the first device layer via the interface portion. In addition, the interface portion provides a communication relationship between the first device layer and the second device layer.

In one aspect of the invention, a first via-hole is formed in a first insulating layer to expose a portion of a first conductive interconnect. A first end of the first conductive plug is coupled to the first conductive interconnect and a second end of the first conductive plug is coupled to the interface portion. The second via-hole is formed on a bottom surface of the second device layer and exposes a portion of at least one element of the second plurality of semiconductor elements. A first end of the second conductive plug is coupled to the at least one element of the second plurality of semiconductor elements and a second end of the second conductive plug is coupled to the interface portion.

In another aspect of the invention, the second via-hole is formed on a bottom surface of the second device layer and exposes a portion of a first conductive interconnect. In this arrangement, a first end of the second conductive plug is coupled to the first conductive interconnect and a second end of the second conductive plug is coupled to the interface portion.

In another aspect of the invention, the first via-hole is formed on the first insulating layer and exposes a portion of at least one element of the first plurality of semiconductor elements. In this arrangement, a first end of the first conductive plug is coupled to the at least one element of the first plurality of semiconductor elements and a second end of the first conductive plug is coupled to the interface portion.

In another aspect of the invention, the multi-layer integrated semiconductor structure of the present invention includes a first device layer including at least a first doped semiconductor region. A first insulating layer is disposed over the first device layer and includes at least a first via-hole. A first conductive material is disposed in the first via-hole. The first device layer further includes an interface portion, which includes a conductive material that is disposed over at least the first conductive material, which is exposed from the first via-hole.

The multi-layer integrated semiconductor structure further includes a second device layer having at least a second doped semiconductor region disposed on a top surface of a substrate and includes at least a second via-hole. A second conductive material is disposed in the second via-hole. The second device layer is positioned and aligned in a contact relationship with the first device layer for coupling the first and second device layers, via the interface portion. In this arrangement, the interface portion provides a communication relationship between the first device layer and the second device layer.

In one aspect of the invention, the first via-hole is formed on the first insulating layer and exposes a first conductive interconnect element. The first conductive material includes a first end coupled to the first conductive interconnect element and a second end coupled to the interface portion. The second via-hole is formed on a bottom surface of the second device layer and exposes a portion of the second doped semiconductor region. The second conductive material includes a first end coupled to the second doped semiconductor region and a second end coupled to the interface portion.

In another aspect of the invention, the second via-hole is formed on a bottom surface of the second device layer and exposes a portion of a first conductive interconnect. In this arrangement, the second conductive material includes a first end coupled to the first conductive interconnect and a second end coupled to the interface portion.

In another aspect of the invention, the second via-hole is formed on a top surface of the second device layer and exposes a portion of a first conductive interconnect. In this arrangement, the second conductive material includes a first end coupled to the first conductive interconnect and a second end coupled to a second interface portion. In another embodiment, the second via-hole is formed on a top surface of the second device layer and exposes a portion of the second doped semiconductor region. In this arrangement, the second conductive material includes a first end coupled to the second doped semiconductor region and a second end coupled to a second interface portion.

In another aspect of the invention, the first via-hole is formed on the first insulating layer and exposes a portion of the first doped semiconductor region. In this arrangement, the first conductive material includes a first end coupled to the first doped semiconductor region and a second end coupled to the interface portion.

In another aspect of the invention, the first device layer is constructed and arranged to operate using at least one of electronic components, optical components or micro-electromechanical components. Furthermore, the second device layer is constructed and arranged to operate using at least one of electronic components, optical components or micro-electromechanical components.

In another aspect, a multi-layer integrated semiconductor structure (e.g., die-to-wafer structure) is set forth in accordance with principles of the present invention. The multi-layer integrated semiconductor structure includes a semiconductor wafer having a plurality of semiconductor structures, each of which includes a plurality of semiconductor elements. At least a first conductive bonding interface segment is disposed over at least a first semiconductor structure of the plurality of semiconductor structures of the semiconductor wafer. The first conductive bonding interface is adapted to be in an electrical communication relationship with at least a first semiconductor element of the first semiconductor structure.

The multi-layer integrated semiconductor structure further includes at least a second semiconductor structure, which also includes a plurality of semiconductor elements. The second semiconductor structure is coupled to the first semiconductor structure via the first conductive bonding interface segment. Furthermore, the first conductive bonding interface segment is adapted to be in an electrical communication relationship with at least a second semiconductor element of the plurality of semiconductor elements of the second semiconductor structure. In this arrangement, at least the first semiconductor element of the first semiconductor structure can electrically communicate with at least the second semiconductor element of the second semiconductor structure, via the first conductive bonding interface segment.

In another aspect, a multi-layer integrated semiconductor structure (e.g., multiple die-to-die structure) is set forth in accordance with principles of the present invention. The multi-layer integrated semiconductor structure includes at least a first semiconductor structure including a first plurality of conductive elements. A plurality of conductive bonding interface segments are disposed over the first semiconductor structure. Each of the plurality of conductive bonding interface segments are adapted to be in an electrical communication relationship with one or more of the conductive elements of the first semiconductor structure.

The multi-layer integrated semiconductor structure further includes at least a second semiconductor structure including a second plurality of conductive elements. The second semiconductor structure is coupled to the first semiconductor structure via at least a first segment of the plurality of conductive bonding interface segments. At least a third semiconductor structure is also provided on the multi-layer integrated semiconductor structure. The third semiconductor structure includes a third plurality of conductive elements, which are coupled to the first semiconductor structure, via at least a second segment of the plurality of conductive bonding interface segments. In this arrangement, the first plurality of conductive elements of the first semiconductor structure, the second plurality of conductive elements of the second semiconductor structure and the third plurality of conductive elements of the third semiconductor structure can inter communicate via the first and second segments of the plurality of conductive bonding interface segments.

### BRIEF DESCRIPTION OF THE DRAWING

The foregoing and other objects of this invention, the various features thereof, as well as the invention itself, can be more fully understood from the following description, when read together with the accompanying drawings in which:

FIG. 1 is an exemplary cross-sectional view of a multi-layer integrated semiconductor structure according to the present invention;

FIG. 2 is another embodiment of a multi-layer integrated semiconductor structure;

FIG. 3 is yet another embodiment of a multi-layer integrated semiconductor structure;

FIG. 4 is yet another embodiment of a multi-layer integrated semiconductor structure;

FIG. 5 is a flow chart illustrating process steps for fabricating the multi-layer integrated semiconductor structures of FIGS. 1-4;

FIG. 6 is an embodiment of a multi-layer integrated semiconductor structure including a die-to-wafer structure; and

FIG. 7 is an embodiment of a multi-layer integrated semiconductor structure including a multiple die-to-die structure.

### DETAILED DESCRIPTION OF THE INVENTION

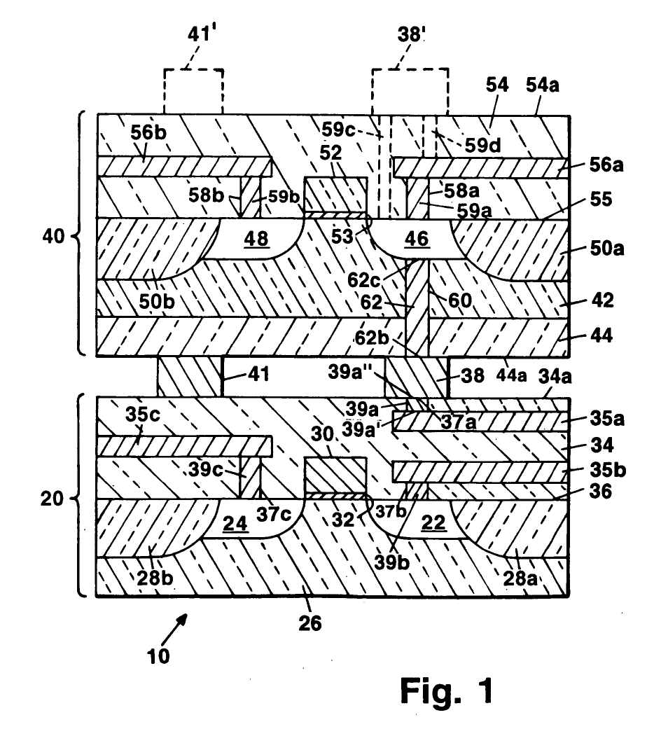

Referring to FIG. 1, an exemplary multi-layer integrated semiconductor structure 10 includes at least a first device layer 20 and a second device layer 40. The first and second device layers 20, 40 represent separate semiconductor structures, which each may include a number of layers. For example, the first device layer 20 may correspond to a first semiconductor wafer having a first plurality of integrated circuits thereon and the second device layer 40 may correspond to a second semiconductor wafer 40 having a second plurality of integrated circuits thereon. On the other hand, the device layers 20, 40 may represent individual dies cut from a wafer. The first and second device layers 20, 40 are coupled (e.g. bonded together) by one or more interface portions 38, 41. In an embodiment, interface portion 38 serves to electronically and/or photonically interconnect device layers 20 and 40 with each other. The interface 38 may also serve to provide adhesive and/or bonding properties for securely coupling device layers 20 and 40. Interface portion 41 may serve to further provide adhesive and/or bonding properties for securely coupling device layers 20 and 40. Further, additional semiconductor structures (not shown) can be stacked and bonded on the device layer 40, via interfaces 38′, and/or 41′, which promotes scalability, as will be described in further detail below.

The first device layer 20 includes a substrate 26 having a pair of doped regions 22, 24 formed therein. The doped regions 22, 24 can, for example, correspond to a source region 22 and a drain region 24 of a transistor. The first device layer 20 further includes insulating regions 28a, 28b. Insulating regions 28a, 28b can be provided, for example, as an oxide film disposed on the silicon substrate 26 adjacent to the doped regions 22, 24, respectively.

In the case where doped regions 22, 24 correspond to source and drain regions 22, 24, the first device layer 20 further includes a gate region 30 disposed over the silicon substrate 26 at a channel region defined between the source 22 and drain 24 regions. An insulating material 32, such as an oxide film, is provided between the gate region 30 and the silicon substrate 26. Thus, source, drain and gate regions 22, 24, 30 form the electrodes and/or terminals of a field effect transistor (FET).

It should be understood that although reference is made herein to specific types of circuit elements, such reference is made for convenience and clarity in the description and is not intended to be limiting. It should be appreciated that the device layer 20 typically includes thousands or millions of doped regions and that circuit elements other that FET's can be formed by doped regions.

One or more layers of dielectric material 34 are disposed over a top surface 36 of the first device layer for covering a plurality of the horizontally oriented interconnects or conductive circuit interconnects 35a, 35b, 35c, which are formed over the surface 36 of the first device layer 20. A plurality of vertically oriented via-holes 37a, 37b, 37c, are formed in the dielectric material 34. In one embodiment, the via-holes 37a, 37b, 37c may, for example, be filled with a conductive plug or material 39a, 39b, 39c, such as tungsten.

The interface portion 38, which can be formed of conductive bonding material, such as copper or a copper alloy or other suitably appropriate conductive and/or bonding material, is disposed on the dielectric material 34. The conductive plugs or material 39a, 39b, 39c are provided in the dielectric material 34 so as to interconnect one or more of the conductive circuit interconnects 35a, 35b, 35c to at least one of the source 22 or drain 24 regions of the first device layer 20 and/or to interconnect one or more of the conductive circuit interconnects 35a, 35b, 35c to the conductive interface portion 38. Although not specifically shown in FIG. 1, the conductive plugs or material 39a, 39b, 39c may also serve to couple two or more of the interconnects 35a, 35b, 35c.

The second device layer 40 includes a silicon substrate 42 having an insulating layer 44. Insulating layer 44 may be provided, for example, as an oxide layer. Similar to the first device layer 20, the second device layer 40 also includes a pair of doped regions 46, 48 which may, for example, correspond to source and a drain regions 46, 48 formed in the silicon substrate 42. The second device layer 40 also includes insulating regions 50a, 50b. Insulating regions 50a, 50b may be provided, for example, as an oxide film, disposed on the silicon substrate 42 adjacent to the source 46 and drain 48 regions, respectively. Device layer 40 further includes a gate region 52 formed on the silicon substrate 42 over a channel region defined between the sources 46 and drains 48 regions. An insulating material 53, such as an oxide film, is provided between the gate region 52 and the silicon substrate 42.

One or more layers of dielectric material 54 are disposed over a surface 55 of the second device layer 40 for covering a plurality of the horizontally oriented interconnects or conductive circuit interconnects 56a, 56b, which are formed over the surface 55 of the second device layer 40. A plurality of vertically oriented via-holes 58a and 58b are formed in the dielectric material 54. In one embodiment, the via-holes 58a, 58b are each filled with a conductive material 59a, 59b, such as tungsten. The conductive material or plugs 59a, 59b are arranged on the dielectric material 54 to interconnect the conductive circuit interconnects 56a, 56b to respective ones of the source 46 or drain 48 regions of the second device layer 40. Although not specifically shown in FIG. 1, the conductive material or plugs may 59a and 59b may also be used to interconnect horizontal connections, such as the conductive circuit interconnects 56a and 56b, or other conductive circuit interconnects (not shown), which may be located on similar or different levels of device layer 40.

In the exemplary embodiment of FIG. 1, a first via-hole 37a of the plurality of vertically oriented via-holes 37a, 37b, 37c is provided in the dielectric material 34 of the first device layer 20. The first via-hole 37a extends from a top surface 34a of the dielectric material 34 downwardly to and exposes a portion of a first conductive interconnect 35a of the plurality of conductive interconnects 35a, 35b, 35c. The first via-hole 37a is dimensioned to accept a conductive plug 39a or other conductive material having a first end 39a′ coupled to the first conductive interconnect 35a and a second end 39a″ coupled to the conductive interface portion 38.

A second via-hole 60 provided in the second device layer 40 extends from a bottom surface 44a of the insulating material 44 upwardly through the silicon substrate 42 to expose a portion of the doped region 46 of the second device layer 40. The second via-hole 60 is dimensioned to accept a conductive plug 62 or other conductive material having a first end 62a coupled to the doped region 46 of the second device layer 40 and a second end 62b coupled to the conductive interface portion 38. In this arrangement, the first conductive plug 39a, the conductive interface portion 38 and the second conductive plug 62 collectively provide a direct vertical interconnect between the first conductive interconnect 35a of the first device layer 20 and the doped region 46 of the second device layer 40.

It should be understood that another conductive interface portion 38′ can be disposed on a top surface 54a of the second device layer 40 in a region where optional conductive plugs 59c, 59d are formed. In this arrangement, an additional device layer (not shown) can be integrated on top of the second device layer 40 in a similar manner as the second device layer 40 is integrated with the first device layer 20. This process can be repeated to stack an infinite number of device layers (not shown) onto the previously defined top device layer for promoting semiconductor structure scalability.

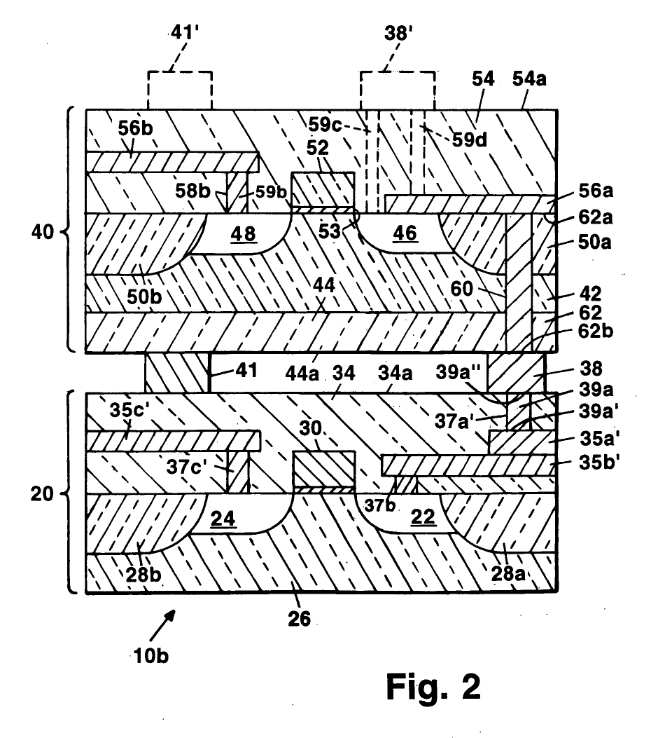

Referring to FIG. 2, in which like elements of FIG. 1 are provided having like reference designations, another exemplary embodiment of a multi-layer integrated semi-conductor structure 10b in accordance with the present invention is shown. The multi-layer integrated semi-conductor structure 10b is similar to that described above in conjunction with FIG. 1.

In the multi-layer semiconductor structure 10b, a first via-hole 37a′ extends from the top surface 34a of the dielectric material 34 downwardly to expose a portion of a first conductive interconnect 35a′. The first via-hole 37a′ is dimensioned to accept a conductive plug 39a or other conductive material having a first end 39a′ coupled to the first conductive interconnect 35a′ and a second end 39a″ coupled to the conductive interface portion 38.

A second via-hole 60 provided in the second device layer 40 extends from a bottom surface 44a of the insulating material 44 upwardly through the insulating material 44, the silicon substrate 42 and the insulating material 50a located adjacent the doped region 46 and exposes a portion of a first conductive interconnect 56a of the plurality of conductive interconnects 56a, 56b in the second device layer 40. The second via-hole 60 is dimensioned to accept a conductive plug 62 or other conductive material having a first end 62a coupled to the first conductive interconnect 56a and a second end 62b coupled to the conductive interface portion 38. In this arrangement, the first conductive plug 39a, the conductive interface portion 38 and the second conductive plug 62 collectively provide a direct vertical interconnect between the first conductive interconnect 35a′ of the first device layer 20 and the first conductive interconnect 56a of the second device layer 40.

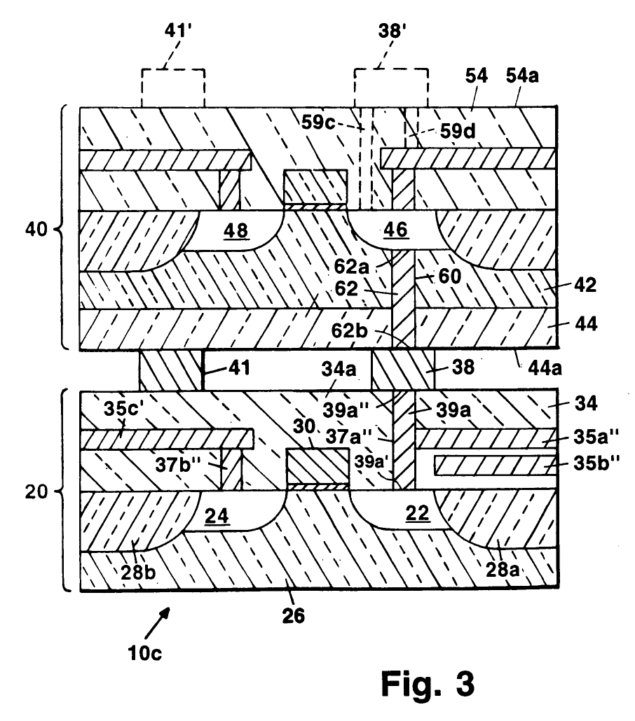

Referring to FIG. 3, in which like elements of FIGS. 1 and 2 are provided having like reference designations, another exemplary embodiment of a multi-layer integrated semiconductor structure 10c in accordance with the present invention is shown. The multi-layer integrated semiconductor structure 10c is similar to that described above in conjunction with FIGS. 1 and 2.

In the multi-layer semiconductor structure 10c, a first via-hole 37a″ provided in the first device layer 20 extends from a top surface 34a of the dielectric material 34 downwardly to expose a portion of the doped region 22 of the first device layer 20. The first via-hole 37a″ is dimensioned to accept a conductive plug 39a or other conductive material having a first end 39a′ coupled to the doped region 22 and a second end 39a″ coupled to the conductive interface portion 38. Furthermore, one or more of the plurality of conductive interconnects 35a″, 35b″, 35c″, such as conductive interconnect 35a″, can be coupled to the conductive plug 39a for providing an electrical signal path or other communication relationship between the conductive plug 39a and other elements (not shown), which may be located elsewhere in the structure 10C.

A second via-hole 60 provided in the second device layer 40 extends from the bottom surface 44a of the insulating material 44 upwardly through the insulating material 44 and through the substrate 42 to expose a portion of a doped region 46 of the second device layer 40. The second via-hole 60 is dimensioned to accept a conductive plug 62 or other conductive material having a first end 62a coupled to the region 46 of the second device layer 40 and a second end 62b coupled to the conductive interface portion 38. In this arrangement, the first conductive plug 39a, the conductive interface portion 38 and the second conductive plug 62 collectively provide a direct vertical interconnect between the doped region 22 of the first device layer 20 and the doped region 46 of the second device layer 40.

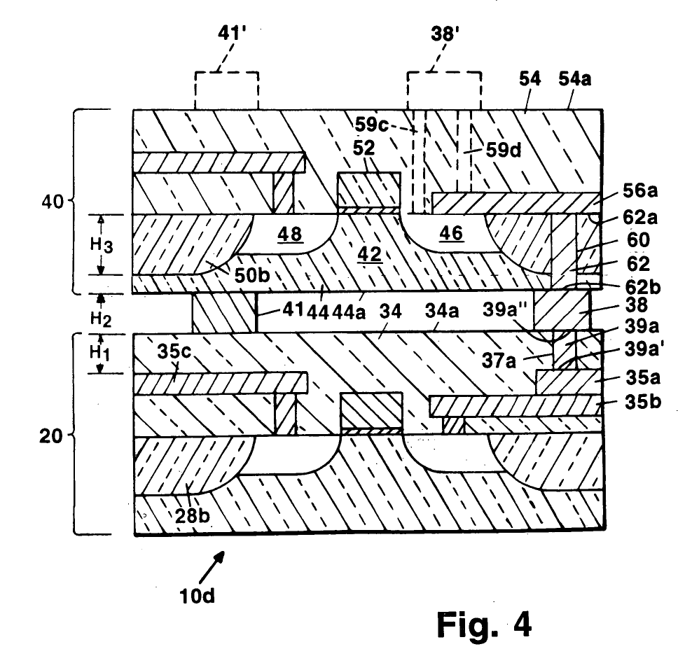

Referring to FIG. 4, in which like elements of FIGS. 1-3 are provided having like reference designations, another exemplary embodiment of a multi-layer integrated semiconductor structure 10d in accordance with the present invention is shown. The multi-layer integrated semiconductor structure 10d is similar to that shown and described above in conjunction with FIGS. 1-3.

In the multi-layer integrated semiconductor structure 10d, a first via-hole 37a provided in the dielectric material 34 defined on first device layer 20 extends from the top surface 34a of the dielectric material 34 downwardly to expose a portion of a first conductive interconnect 35a. A height “H₁” of the dielectric material 34 of the first device layer 20 can be controlled to control the depth of the first via-hole 37a, which permits process optimization (e.g., control of via-hole 37a aspect ratio, i.e., the ratio of via-hole 37a height over via-hole 37a diameter). The first via-hole 37a is dimensioned to accept a conductive plug 39a or other conductive material having a first end 39a′ coupled to the first conductive interconnect 35a and a second end 39a″ coupled to the conductive interface portion 38.

The second via-hole 60 is formed on the second device layer 40 and extends from the bottom surface 44a of the insulating material 44 upwardly through the insulating material 44, the silicon substrate 42 and the insulating material 50a located adjacent to the source region 46 for exposing a portion of a first conductive interconnect 56a located on the second device layer 40.

A height “H₂” of the insulating material 44 and a height “H₃” of the silicon substrate 42, which are both defined on the second device layer 40, can each be controlled to control the depth of the second via-hole 60, which permits process optimization and control of via aspect ratios. The second via-hole 60 is dimensioned to accept a conductive plug 62 or other conductive material having a first end 62a coupled to the first conductive interconnect 56a and a second end 62b coupled to the conductive interface portion 38. In this arrangement, the first conductive plug 39a, the conductive interface portion 38 and the second conductive plug 62 collectively provide a direct vertical interconnect between the first conductive interconnect 35a of the first device layer 20 and the first conductive interconnect 56a of the second device layer 40.

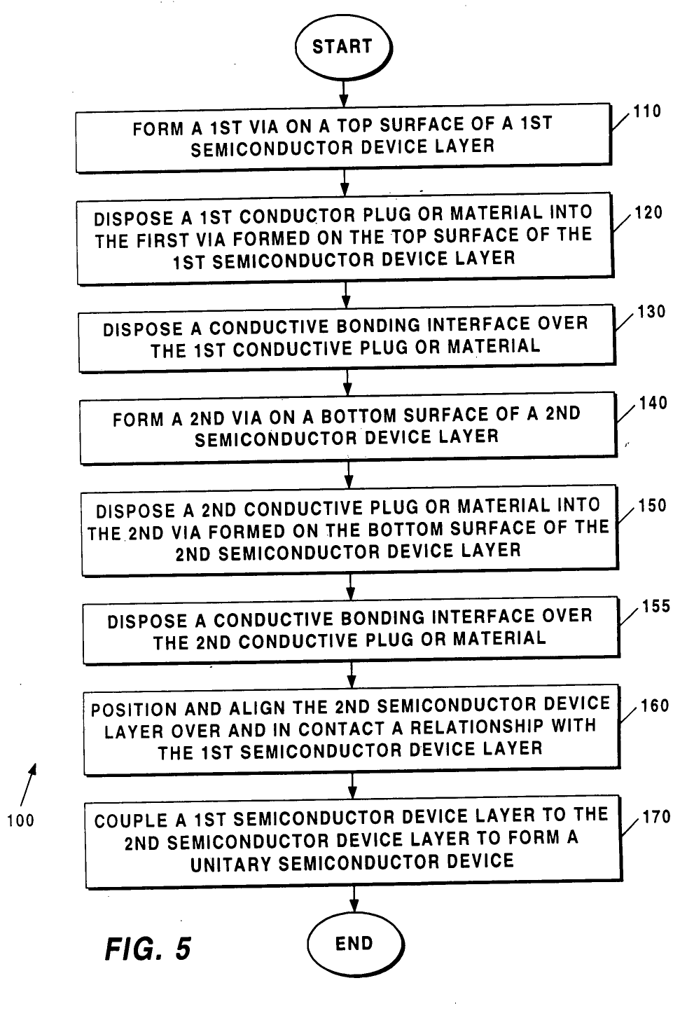

Referring to FIG. 5, an exemplary method 100 of forming any one of the multi-layer integrated semiconductor structures 10 (FIG. 1), 10b (FIG. 2), 10c (FIG. 3) or 10d (FIG. 4) is shown. At step 110, a first device layer (e.g. device layer 20 shown in FIGS. 1-4 above) is processed to form at least a first via-hole (e.g. via-hole 37a shown above in FIG. 1) having a predetermined depth. In one embodiment, the first via-hole 37a exposes a portion of a conductive metal member defined on the first device layer 20, such as the signal interconnect 35a.

In another embodiment, such as the embodiment shown in FIG. 3, one end of the first via-hole (e.g. via-hole 37a″ in FIG. 3) extends downwardly from a first or top surface 34a of the device layer 20 (FIG. 3). The first via-hole extends downwardly a predetermined depth to expose a portion of a doped region 22 defined on the first device layer 20 (e.g. region 22 of device layer 20 in FIG. 3).

At step 120, a first conductive plug or material is disposed in the first via-hole formed on the top surface of the first device layer 20. At step 130, a conductive interface portion (e.g. interface portion 38 in FIGS. 1-4), which may be provided, for example, as copper or copper alloy, is disposed over at least the first conductive plug.

At step 140, the method 100 further includes processing a second device layer (e.g. device layer 40 in FIG. 1) to form at least a second via-hole (e.g. via-hole 60 in FIG. 1) on a bottom surface thereof and having a predetermined depth. In one embodiment, the second via-hole exposes a portion of a doped region 46 defined on the second device layer 40 (e.g. source region 46 in FIGS. 1-4). In another embodiment, the second via-hole exposes a portion of a conductive metal member defined on the second device layer 40 (such as the signal interconnect 56a).

At step 150, a second conductive plug 62 or material is disposed in the second via-hole 60 formed on the bottom surface 44a of the second device layer 40. The second conductive plug can include similar material as the first conductive plug 39a.

At step 155, another conductive interface portion (not shown), which is similar to the conductive interface 38 disposed on the first conductive plug, is disposed on at least the second conductive plug 62. This conductive interface portion disposed on the second conductive pug 62 combines with conductive interface 38 disposed on the first conductive plug when the first device layer 20 and the second device layer 40 are coupled together, which will be described in further detail below.

At step 160, the second device layer 40 is positioned and aligned over and in a contact relationship with the first device layer 20. At step 170, the first device layer 20 is coupled to the second device layer 40, via the conductive interface portion 38, to form a unitary multi-layer semiconductor device structure, such as the structures 10, 10b, 10c or 10d respectively depicted in FIGS. 1-4 above.

Although not specifically shown, it should be understood that the multi-layer semiconductor structures 10, 10b, 10c or 10d described above in conjunction with FIGS. 1, 2, 3 and 4, respectively are each scaleable to include a plurality of additional device layers (not shown), such as third and fourth device layers. In addition, it should be understood that the first device layer 20 can be constructed and arranged to operate using electronic components, such as digital signal processors (DSPs) and memories, as well as a number of other digital and/or analog based devices. In addition, the first device layer 20 can be constructed and arranged to operate using optical components, such as optical cross-point switches and optical-to-electronic converters, as well as a number of other optical based devices. Furthermore, the first device layer 20 can be constructed and arranged to operate using micro-electromechanical (MEM) components, such as micro-motors, sensors and actuators, as well as a number of other MEM based devices.

It should be further understood that the second device layer 40 can be similarly constructed and arranged to operate as the first device layer 20, as described above. In one embodiment, the first device layer 20 and the second device layer 40 can each be constructed and arranged to operate using similar components and/or devices, as described above, to form a unitary multi-layer structure. In another embodiment, the first device layer 20 and the second device layer 40 can each be constructed and arranged to operate using dissimilar components and/or devices, as described above, to form a unitary mixed signal multi-layer structure.

Although the multi-layer semiconductor structures 10, 10b, 10c or 10d described above in conjunction with FIGS. 1, 2, 3 and 4, respectively represent the coupling of device layer 20 and device layer 40, it should be understood that in an exemplary embodiment, the device layer 20 can represent a single lower die element and the device layer 40 can represent a single upper die element. In this exemplary embodiment, the multi-layer semiconductor structures 10, 10b, 10c or 10d described above in conjunction with FIGS. 1, 2, 3 and 4, respectively show die-to-die bonding using the interface portion 38 to couple the lower die element to the upper die element.

Furthermore, in another exemplary embodiment, the device layer 20 can represent one element of a plurality of elements located on a single lower semiconductor wafer (not shown) and the device layer 40 can represent one element of a plurality of elements located on a single upper semiconductor wafer (not shown). In this exemplary embodiment, the multi-layer semiconductor structures 10, 10b, 10c or 10d described above in conjunction with FIGS. 1, 2, 3 and 4, respectively show a portion of a wafer-to-wafer bonding using the interface portion 38 to couple one element of the plurality of elements of the lower wafer to one element of the plurality of elements of the upper wafer.

Yet further, in another exemplary embodiment, the device layer 20 can include a first predetermined surface area. Moreover, the first predetermined surface area can be formed of a first predetermined size, shape or geometry, such as a rectangular or square die or portion thereof, a round wafer or portion thereof, or a rectangular or square substrate of a flat panel display or portion thereof. Similarly, the device layer 40 can include a second predetermined surface area. The second predetermined surface area can be formed of a second predetermined size, shape or geometry, such as a rectangular or square die or portion thereof, a round wafer or portion thereof, or a rectangular or square flat panel display substrate or portion thereof. Thus, in accordance with embodiments of the present invention, the device layers 20, 40 can be coupled together regardless of their respective sizes, shapes or geometries to form the multi-layer semiconductor structures 10, 10b, 10c or 10d described above in conjunction with FIGS. 1, 2, 3 and 4.

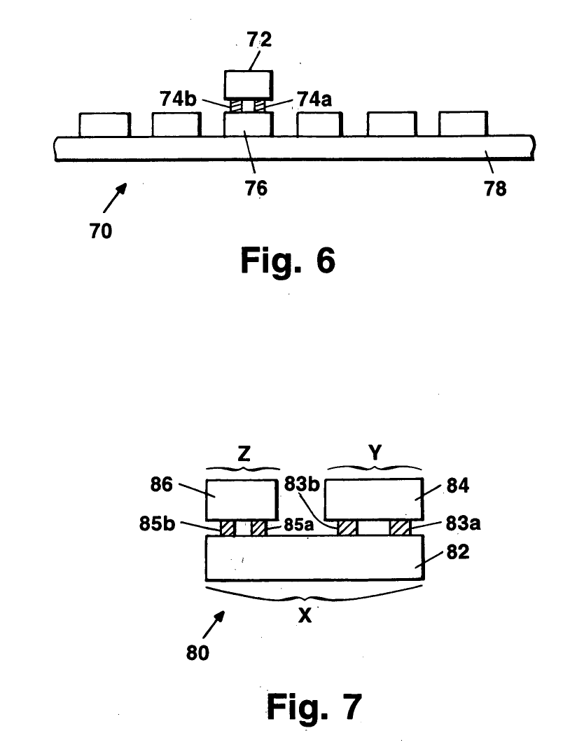

Referring to FIG. 6, an embodiment of a die-to-wafer structure 70 is provided, which includes a first die 72 disposed over and coupled to a second die 76, via a conductive bond film 74a. Optionally, the bond film 74b, e.g., adhesive material, may also be provided to further strengthen the bond formed between the first die 72 and the second die 76, which is provided as part of a larger integrated circuit or wafer 78. The bond films 74a and 74b or segments may be provided as any of the types described above in conjunction with FIGS. 1-4 (e.g., conductive interface portion 38 and interface portion 41, respectively) and serves to bond the first die 72 to the second die 76, as described above. Thus, to provide the die-to-wafer structure 70, the bond films 74a, 74b can be first applied to a wafer (not shown) of which the first die 72 is a part. While the first die 72 is part of the wafer, the bond film can be patterned or otherwise disposed on the die 72 using a variety of different techniques, including those techniques described in copending U.S. patent application Ser. No. ______, filed on Sep. 5, 2003, which is entitled METHOD OF FORMING A MULTI-LAYER SEMICONDUCTOR STRUCTURE HAVING A SEAMLESS BONDING INTERFACE, which is commonly assigned to the Assignee of the present application and which is hereby incorporated by reference in its entirety. Once the bond films 74a, 74b are disposed on the wafer including the first die 72, the first die 72 is cut or otherwise separated from the wafer.

Alternatively, the bond films 74a, 74b can be first disposed on the second die 76 and then the first die 72 and second die 76 are aligned. In one embodiment, the first die 72 is aligned in a predetermined position on the wafer 78. In the example of FIG. 6, the first die 72 is aligned over the second die 76, which is provided as part of the wafer 78. It should be appreciated that while aligning the first die 72 over the second die 76, it is necessary to secure the wafer 78 or the die 72 so that the first die 72 can be properly aligned with the second die 76. It should also be appreciated that portions of the bond films 74a, 74b can be disposed on each of the first and second dies 72, 76 prior to aligning and bonding the first and second dies 72, 76, as described above.

Once the first die 72 and the second die 76 are properly aligned, at least the first die 72 is exposed to a method for bonding the first and second dies 72, 76, via the bond films 74a, 74b, which is similar to that described in FIG. 1 of commonly assigned U.S. patent application Ser. No. ______, as described above. The particular temperatures and pressures used for bonding the first and second dies 72, 76 will depend upon a variety of factors, including but not limited to, the specific material from which the bond film 74 is provided, as well as the size, shape and material from which the first die 72 is provided, as well as the size, shape and material from which the second die 76 is provided.

Referring to FIG. 7, an embodiment of a multiple die-to-die structure 80, is provided, which includes a first die 82 bonded to a second die 84, via first and second bond films 83a, 83b. In the exemplary embodiment, the bond films 83a, 83b are similarly constructed and arranged as the bonding films 74a, 74b, as described above with respect to FIG. 6. In FIG. 7, the multiple die-to-die structure 80 further includes a third die 86 coupled to the first die 82, via third and fourth bond films 85a, 85b. In the exemplary embodiment, the bond films 85a, 85b are also similarly constructed and arranged as the bonding films 74a, 74b, as described above with respect to FIG. 6. In FIG. 7, the first, second and third dies 82, 84, 86 may be bonded together using the first and second bond films 83a, 83b, and the third and fourth bond films 85a, 85b, as described above, using a method which is also similar to that described in FIG. 1 of commonly assigned U.S. patent application Ser. No. ______, as described above.

It should be understood that the multiple die-to-die structure 80, including the first, second and third dies 82, 84, 86, is provided for illustration purposes and that the multiple die-to die structure 80 can be expanded to include a plurality of semiconductor die structures (not shown). Furthermore, the plurality of die structures, which may each include various die shapes, sizes and/or geometries, can be arranged and bonded to form another multiple die-to-die structure (not shown) having a number of dies that can be stacked to include multiple levels, such as three or more levels of die structures. In the embodiment of the multiple die-to-die structure 80 of FIG. 7, for example, the second and third dies 84, 86 are stacked on and bonded to the first die 82 to form the multiple die-to-die structure 80, which includes two levels (e.g., the first die forming a first level and the second and third dies 84, 86 forming a second level of the multiple die-to-die structure 80). Further, the first die 82 can include a first shape or geometry “X”, the second die 84 can include a second shape or geometry “Y” and the third die 86 can include a third shape or geometry “Z.”

Having thus described at least one illustrative embodiment of the invention, various alterations, modifications and improvements will readily occur to those skilled in the art. Such alterations, modifications and improvements are intended to be within the scope and spirit of the invention. Accordingly, the foregoing description is by way of example only and is not intended as limiting. The invention's limit is defined only in the following claims and the equivalents thereto. All references and publications cited herein are expressly incorporated herein by reference in their entirety.

What is claimed is:

1. A multi-layer integrated semiconductor structure, comprising:
at least a first device layer including a first plurality of semiconductor elements;
a first insulating layer disposed over the first device layer and including at least a first via-hole;
a first conductive plug disposed in the first via-hole;
a first interface portion disposed over at least a portion of the first conductive plug;
at least a second device layer including a second plurality of semiconductor elements and including a second via-hole; and
a second conductive plug disposed in the second via-hole, wherein the second device layer is coupled to the first device layer via the first interface portion and wherein the first interface portion provides a communication relationship between the first device layer and the second device layer.

2. The multi-layer integrated semiconductor structure of claim 1 further comprising a first conductive interconnect element disposed in the first insulating layer and wherein the first via-hole is provided in the first insulating layer to expose at least a portion of the first conductive interconnect element.

3. The multi-layer integrated semiconductor structure of claim 2, wherein the first conductive plug includes a first end coupled to the first conductive interconnect element and a second end coupled to the first interface portion.

4. The multi-layer integrated semiconductor structure of claim 3, wherein the second via-hole is formed on a bottom surface of the second device layer and exposes a portion of at least one element of the second plurality of semiconductor elements.

5. The multi-layer integrated semiconductor structure of claim 1, wherein the second via-hole is formed on a top surface of the second device layer and exposes a portion of at least one element of the second plurality of semiconductor elements.

6. The multi-layer integrated semiconductor structure of claim 5, wherein the second conductive plug includes a first end coupled to at least one element of the second plurality of semiconductor elements and a second end coupled to at least a portion of a second interface portion disposed on the top surface of the second device layer.

7. The multi-layer integrated semiconductor structure of claim 4, wherein the second conductive plug includes a first end coupled to the at least one element of the second plurality of semiconductor elements and a second end coupled to the first interface portion.

8. The multi-layer integrated semiconductor structure of claim 3, wherein the second via-hole is formed on a bottom surface of the second device layer and exposes a portion of a second conductive interconnect.

9. The multi-layer integrated semiconductor structure of claim 8, wherein the second conductive plug includes a first end coupled to the second conductive interconnect and a second end coupled to the first interface portion.

10. The multi-layer integrated semiconductor structure of claim 3, wherein the second via-hole is formed on a top surface of the second device layer and exposes a portion of at least a second conductive interconnect.

11. The multi-layer integrated semiconductor structure of claim 10, wherein the second conductive plug includes a first end coupled to the second conductive interconnect and a second end coupled to at least a portion of a second interface portion disposed on the top surface of the second device layer.

12. The multi-layer integrated semiconductor structure of claim 1, wherein the first via-hole exposes a portion of at least one element of the first plurality of semiconductor elements.

13. The multi-layer integrated semiconductor structure of claim 12, wherein the first conductive plug includes a first end coupled to the at least one element of the first plurality of semiconductor elements and a second end coupled to the first interface portion.

14. The multi-layer integrated semiconductor structure of claim 1, wherein the first interface portion includes a conductive material.

15. The multi-layer integrated semiconductor structure of claim 14, further including a second interface portion disposed between the first and second device layers.

16. The multi-layer integrated semiconductor structure of claim 15, wherein the second interface portion includes an adhesive material.

17. A multi-layer integrated semiconductor structure, comprising:
at least a first device layer including at least a first doped semiconductor region;
a first insulating layer disposed over the first device layer and including at least a first via-hole;
a first conductive material disposed in the first via-hole;
an interface portion disposed over at least the first conductive material;
at least a second device layer including at least a second doped semiconductor region and including a second via-hole; and
a second conductive material disposed in the second via-hole, wherein the second device layer is coupled to the first device layer via the interface portion and wherein the interface portion provides a communication relationship between the first device layer and the second device layer.

18. The multi-layer integrated semiconductor structure of claim 17 further comprising a first conductive interconnect element disposed in the first insulating layer and wherein the first via-hole is formed on the first insulating layer and exposes at least a portion of the first conductive interconnect element.

19. The multi-layer integrated semiconductor structure of claim 18, wherein the first conductive material includes a first end coupled to the first conductive interconnect element and a second end coupled to the interface portion.

20. The multi-layer integrated semiconductor structure of claim 17, wherein the second via-hole is formed on a bottom surface of the second device layer and exposes a portion of the second doped semiconductor region.

21. The multi-layer integrated semiconductor structure of claim 17, wherein the second via-hole is formed on a top surface of the second device layer and exposes a portion of the second doped semiconductor region.

22. The multi-layer integrated semiconductor structure of claim 21, wherein the second conductive material includes a first end coupled to the second doped semiconductor region and a second end coupled to another interface portion disposed on the top surface of the second device layer.

23. The multi-layer integrated semiconductor structure of claim 17, wherein the second via-hole is formed on a bottom surface of the second device layer and exposes a portion of a first conductive interconnect.

24. The multi-layer integrated semiconductor structure of claim 23, wherein the second conductive material includes a first end coupled to the first conductive interconnect and a second end coupled to the interface portion.

25. The multi-layer integrated semiconductor structure of claim 17, wherein the first via-hole exposes a portion of the first doped semiconductor region.

26. The multi-layer integrated semiconductor structure of claim 25, wherein the first conductive material includes a first end coupled to the first doped semiconductor region and a second end coupled to the interface portion.

27. The multi-layer integrated semiconductor structure of claim 17, wherein the interface portion includes a conductive material.

28. The multi-layer integrated semiconductor structure of claim 17, wherein the first conductive material includes a first conductive plug.

29. The multi-layer integrated semiconductor structure of claim 17, wherein the second conductive material includes a second conductive plug.

30. The multi-layer integrated semiconductor structure of claim 17, wherein the first device layer is constructed and arranged to operate using at least one of electronic components, optical components or micro-electromechanical components.

31. The multi-layer integrated semiconductor structure of claim 17, wherein the second device layer is constructed and arranged to operate using at least one of electronic components, optical components or micro-electromechanical components.

32. The multi-layer integrated semiconductor structure of claim 17, wherein the first device layer includes at least one die element.

33. The multi-layer integrated semiconductor structure of claim 17, wherein the second device layer includes at least one die element.

34. The multi-layer integrated semiconductor structure of claim 17, wherein the first device layer includes at least one die element of a plurality of die elements located on a semiconductor wafer.

35. The multi-layer integrated semiconductor structure of claim 17, wherein the second device layer includes at least one die element of a plurality of die elements located on a semiconductor wafer.

36. The multi-layer integrated semiconductor structure of claim 17, wherein the first device layer includes a first predetermined surface area and the second device layer includes a second predetermined surface area whereby the first predetermined surface area differs from the second predetermined surface area.

37. The multi-layer integrated semiconductor structure of claim 17, wherein the first device layer includes a first predetermined surface area and the second device layer includes a second predetermined surface area whereby the first predetermined surface area is substantially equivalent to the second predetermined surface area.

38. The multi-layer integrated semiconductor structure of claim 17, wherein the first device layer includes a first predetermined geometry.

39. The multi-layer integrated semiconductor structure of claim 17, wherein the second device layer includes a second predetermined geometry.

40. A multi-layer semiconductor structure, comprising:
a semiconductor wafer including a plurality of semiconductor structures each of which includes a plurality of semiconductor elements;
at least a first conductive bonding interface segment disposed over at least a first semiconductor structure of the plurality of semiconductor structures of the semiconductor wafer and being in an electrical communication relationship with at least a first semiconductor element of the first semiconductor structure;
at least a second semiconductor structure including a plurality of semiconductor elements being coupled to the first semiconductor structure via the first conductive bonding interface segment, wherein the first conductive bonding interface segment is in an electrical communication relationship with at least a second semiconductor element of the plurality of semiconductor elements of the second semiconductor structure for permitting at least the first semiconductor element of the first semiconductor structure to communicate with at least the second semiconductor element of the second semiconductor structure, via the first conductive bonding interface segment.

41. A multi-layer semiconductor structure, comprising:
at least a first semiconductor structure including a first plurality of conductive elements;
a plurality of conductive bonding interface segments disposed over the first semiconductor structure and each being in an electrical communication relationship with one or more of the conductive elements of the first semiconductor structure;
at least a second semiconductor structure including a second plurality of conductive elements and being coupled to the first semiconductor structure via at least a first segment of the plurality of conductive bonding interface segments;
at least a third semiconductor structure including a third plurality of conductive elements and being coupled to the first semiconductor structure via at least a second segment of the plurality of conductive bonding interface segments, wherein the first plurality of conductive elements of the first semiconductor structure, the second plurality of conductive elements of the second semiconductor structure and the third plurality of conductive elements of the third semiconductor structure are constructed and arranged to inter communicate via the first and second segments of the plurality of conductive bonding interface segments.
